(19) United States
(12) Patent Application Publication
(10) Pub. No.: US 2005/0090084 A1
(43) Pub. Date: Apr. 28, 2005

(54) Method of forming a gate structure

(76) Inventor: Been Jon Woo, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/968,105

(22) Filed: Oct. 20, 2004

(30) Foreign Application Priority Data
Oct. 24, 2003 (CN) 200310108122.4

(51) Int. Cl. H01L 21/336; H01L 21/3205; H01L 21/4763

(52) U.S. Cl. 438/585; 438/591; 438/303

(57) ABSTRACT

A method of forming a gate structure is provided. A semiconductor substrate is provided first. A first insulator is formed on the semiconductor substrate. A plurality of dielectric layer structures are formed separate from each other. A portion of the first insulator is exposed. A second insulator is formed on the dielectric layer structure and the exposed first insulator. A portion of the second insulator and the first insulator are removed to form a plurality of spacer structures and to expose the semiconductor substrate. The spacer structures are positioned between the sidewalls of dielectric layer structure, and the exposed semiconductor substrate is positioned between the spacer structures. A third insulator is formed on the exposed semiconductor substrate. A semiconductor layer is formed on the third insulator, wherein the semiconductor layer is positioned between the spacer structures for a conductive gate. The bottom of the conductive gate is narrower than the top of conductive gate for use as a sub-100 nm transistor.

### BACKGROUND OF THE INVENTION

1. Field of the Invention

The present invention relates to a method of forming a gate structure, in particular, to a method of forming a gate structure having sub 100 nm.

2. Description of the Prior Art

Semiconductor fabrication processes have made possible the fabrication of advanced integrated circuits on a semiconductor wafer. These semiconductor fabrication processes are complex, requiring extensive control and care to avoid fabricating defective integrated circuits. Moreover, within advanced integrated circuits, specialized components are utilized to implement particular functionality. As a result, the advanced integrated circuits undergo a first group of semiconductor fabrication processes to fabricate standard components and undergo a second group of semiconductor fabrication processes to fabricate the specialized components.

Micro-miniaturization, or the ability to fabricate semiconductor devices comprised with sub-micron features, has been directly related to advances in photolithography. Photolithography is the process of transferring geometric shapes in a mask to the surface of a silicon wafer. The transfer of this pattern will allow for the definition of features to be etched in underlying film or to provide a mask for ion implantation. It tends to change the design of the process and device structure to reduce the cost.

### SUMMARY OF THE INVENTION

The present invention provides a method of forming a gate structure, in which a spacer is formed by a nitride layer in order to shrink the size of a transistor.

In order for lower Miller capacitance and wider effective channel length, after forming the conductive gate on the spacer, the bottom of the conductive gate is narrower than the top of the conductive gate, thereby achiving lower Miller capacitance and wider effective channel length.

First, a semiconductor substrate is provided. A first insulator is formed on the semiconductor substrate. A plurality of dielectric layer structures are formed separate from each other. A portion of the first insulator is exposed. A second insulator is formed on the dielectric layer structure and the exposed first insulator. A portion of the second insulator and the first insulator are removed to form a plurality of spacer structures and to expose the semiconductor substrate. The spacer structures are positioned between the sidewalls of the dielectric layer structure, and the exposed semiconductor substrate is positioned between the spacer structures. A third insulator is formed on the exposed semiconductor substrate. A semiconductor layer is formed on the third insulator, wherein the semiconductor layer is positioned between the spacer structures for the conductive gate. The bottom of the conductive gate is narrower than the top of conductive gate for use as a sub-100 nm transistor.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1G are cross-sectional views of a semiconductor device according to embodiments of the present invention.

### DETAILED DESCRIPTION OF THE PREFERRED EMBODIMENTS

According to one embodiment of the present invention, a method of forming a gate structure is provided, which comprises the steps of: providing a silicon substrate; forming a first oxide layer on the silicon substrate; forming a plurality of nitride structures separate from each other on the first oxide layer, wherein the nitride structure exposes a portion of the first oxide layer; forming a second oxide layer on the nitride structure and the exposed oxide layer; removing a portion of second oxide layer and a portion of first oxide layer to form a plurality of spacer structures and exposing a portion of silicon substrate, wherein the spacer structures are positioned on the sidewall of the nitride structure, the exposed silicon substrate are positioned between the spacer structures; forming a third oxide layer on the exposed silicon substrate; forming a plurality of polysilicon structures on the third oxide layer, wherein each polysilicon structure is positioned between the adjacent spacer structures, and the top of polysilicon structure is wider than the bottom of polysilicon structure.

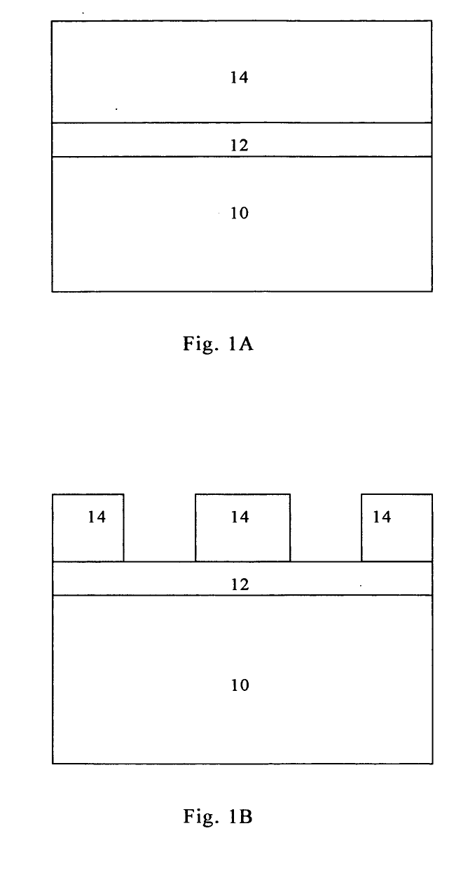

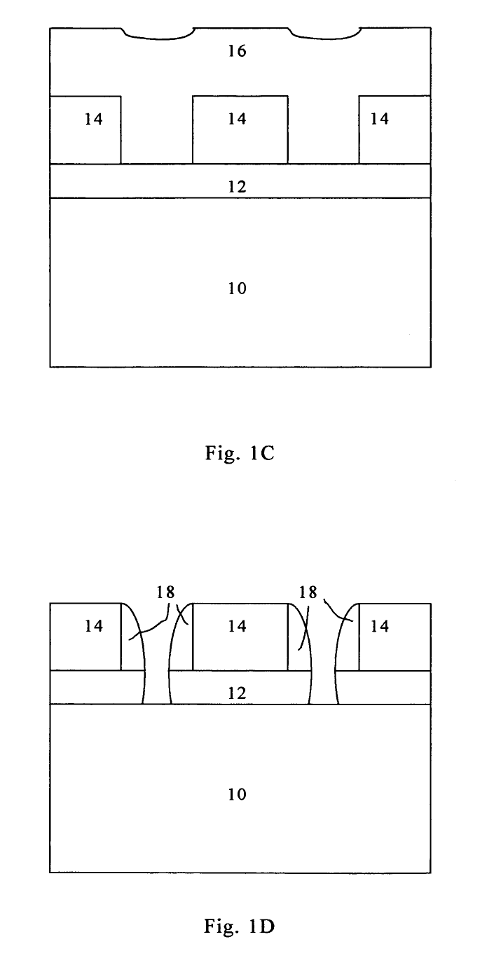

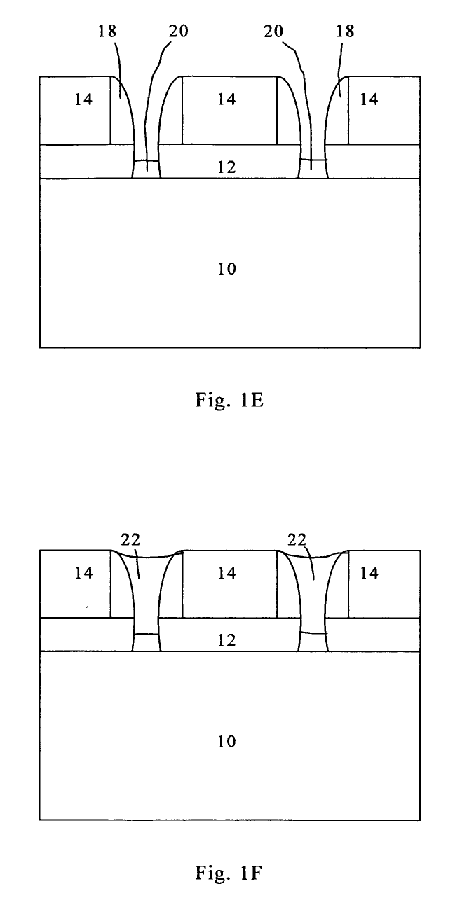

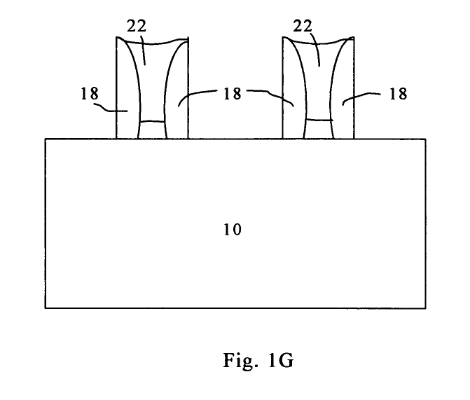

Referring to FIGS. 1A to 1G, the cross-sectional views of a semiconductor device of the present invention are shown. Referring to FIG. 1A, a semiconductor structure 10 is provided first. In one preferred embodiment of the present invention, it should be noted that the required structures are actually formed on the semiconductor structure 10, such as the silicon substrate, N-typed or P-typed well in the silicon substrate or both, and the isolation device such as field oxide or shallow trench isolation are formed by local oxidation. Next, an insulator 12 is formed on the semiconductor structure 10 by using conventional processing. In this embodiment of the present invention, the insulator 12 is a thin pad oxide, and the thickness is about 100 angstroms.

Next, a dielectric layer 14 is formed on the insulator 12. A photoresist layer (not shown) is formed on the dielectric layer 14. The photoresist with pattern is formed by using conventional pattern transfer. The dielectric layer 14 is etched by the photoresist with a pattern used as a etch mask, thereby forming the dielectric layer 14 having the pattern, a plurality of dielectric layer structures separate from each other. A portion of the insulator 12 is exposed, as shown in FIG. 1B. In this embodiment of the present invention, the dielectric layer 14 is formed to a nitride layer thickness of 3000 angstroms by deposition. The distance between dielectric layers 14 is about 120 to 150 nm. It should be noted that the material of the dielectric layer 14 is not limited to a nitride layer. Any material with good selective ratio may be used without departing from the spirit and scope of the present invention

Referring to FIG. 1C, an insulator 16 is covered on the exposed insulator 12 and the patterned dielectric layer 14. In this embodiment of the present invention, the insulator 16 is formed to a thickness of 3000 angstroms of Tetra-Ethyl-Ortho-Silicate (TEOS) by deposition. Next, one portion of the insulator 16 and the exposed insulator 12 are removed by a conventional process, such as etch back. A spacer 18 is formed to a width of 30 nm on the sidewalls of the patterned dielectric layer 16 to expose a portion of the semiconductor structure 10, as shown in FIG. 1D. Accordingly, the surface width of the exposed semiconductor structure 10 is about between 60 and 90 nm. One advantage of the present invention is that a gate structure is formed by using this width of between 60 and 90 nm in the subsequent processing.

Next, a thin insulator 20 is formed on the surface of the exposed semiconductor structure 10, as shown in FIG. 1F. In this embodiment of the present invention, the thin insulator 20, for example, a thin oxide layer, is used as a gate oxide layer. A semiconductor layer 22 is formed on the thin insulator 20, as shown in FIG. 1F. In this embodiment of the present invention, a semiconductor layer 11 may be formed on the entire surface. The semiconductor layer 22 on dielectric layer 14 is planarized and removed by using a proper process, such as chemical mechanical polishing. The planarized semiconductor layer 22 is positioned between spacers and adjacently contacts the spacers with the semiconductor layer 22.

The dielectric layer 14 and the insulator 12 under the dielectric layer 14 are removed, as shown in FIG. 1G. In this embodiment of the present invention, a hot phosphoric acid is used to remove the dielectric layer 14 and the insulator 12, or wet or dry etching is used. Accordingly, being a gate of semiconductor layer 22, the bottom width of the semiconductor structure (where the semiconductor layer 11 contacts the thin insulator 20) is about between 60 and 90 nm. The top width is larger than the bottom width. One advantage of the present invention is that the insulated spacer is formed first, and then a conductive gate is formed. The insulated spacer formed toward the conductive gate can shrink the width of the conductive gate. The source/drain area or lightly doped area formed in the semiconductor structure 10 has lower Miller capacitance and wider effective channel length preventing punch through, thereby the present invention can be applied in making sub-100 nm transistors.

The embodiment above is only intended to illustrate the present invention; it does not, however, to limit the present invention to the specific embodiment. Accordingly, various modifications and changes may be made without departing from the spirit and scope of the present invention as described in the following claims.

1. A method of forming a gate structure, comprising the steps of:
providing a semiconductor substrate;
forming a first insulator on the semiconductor substrate;
forming a plurality of dielectric layer structures separate from each other on the first insulator, wherein the dielectric layer structures expose a portion of the first insulator;
forming a second insulator on the dielectric layer structures and the exposed first insulator;
removing a portion of the second insulator and a portion of the first insulator to form a plurality of spacer structures and to expose a portion of the semiconductor substrate, wherein the spacer structures are positioned on the sidewalls of the dielectric layer structures, and the exposed semiconductor substrate is positioned between the spacer structures;
forming a third insulator on the exposed semiconductor substrate; and
forming a semiconductor layer on the third insulator, wherein the semiconductor layer is positioned between the spacer structures.

2. The method of forming the gate structure of claim 1, further comprising after the step of forming the semiconductor layer, removing the dielectric layer structures and the first insulator under the dielectric layer structures.

3. The method of forming the gate structure of claim 1, further comprising a step of implanting an ion into the semiconductor substrate by using the semiconductor layer and the spacer structures as a mask.

4. The method of forming the gate structure of claim 1, wherein the step of forming the dielectric layer structures comprises the steps of;
depositing a nitride layer on the first insulator;
patterning the nitride layer; and
removing a portion of the nitride layer to form the dielectric layer structures.

5. The method of forming the gate structure of claim 1, wherein the step of forming the second insulator comprises a step of forming a layer of TEOS (Tetra-Ethyl-Ortho-Silicate).

6. The method of forming the gate structure of claim 1, wherein the third insulator comprises an oxide layer.

7. The method of forming the gate structure of claim 1, wherein the semiconductor layer comprises a polysilicon layer.

8. A method of forming a gate structure, comprising the steps of;
providing a silicon substrate;
forming a first oxide layer on the silicon substrate;
forming a plurality of nitride structures on the first oxide layer, wherein the nitride structures expose a portion of the first oxide;
forming a second oxide layer on the nitride structures and the exposed first oxide layer;
removing a portion of the second oxide layer and a portion of the first oxide layer to form a plurality of spacer structures and to expose a portion of the silicon substrate, wherein the spacer structures are positioned on the sidewalls of the nitride structures, and the exposed silicon substrate is positioned between the spacer structures;
forming a third oxide layer on the exposed silicon substrate; and
forming a plurality of polysilicon layers on the third oxide layer, wherein tops of each of the polysilicon structures are positioned between adjacent spacer structures, and the top of the polysilicon structure is wider than the bottom of the polysilicon structure.

9. The method of forming the gate structure of claim 8, further comprising a step of removing the nitride structures and the first oxide layer under the nitride structure.

10. The method of forming the gate structure of claim 8, further comprising a step of implanting an ion into the semiconductor substrate by using the semiconductor layer and the spacer structures as a mask.

11. The method of forming the gate structure of claim 8, wherein the step of forming the nitride structures comprises the steps of;
depositing a nitride layer on the first oxide layer;
patterning the nitride layer; and
removing a portion of the nitride layer to form the nitride structures.
